(19) United States
(12) Patent Application Publication
(10) Pub. No.: US 2026/0196970 A1
(43) Pub. Date: Jul. 9, 2026

(54) RF POWER AMPLIFIERS AND ELECTRONIC DEVICE

(71) Applicant: SMARTER MICROELECTRONICS (SHANGHAI) CO., LTD., Shanghai (CN)

(72) Inventors: Chen CHEN, Shanghai (CN); Yiwei HOU, Shanghai (CN); Zhenfei PENG, Shanghai (CN)

(73) Assignee: SMARTER MICROELECTRONICS (SHANGHAI) CO., LTD., Shanghai (CN)

(21) Appl. No.: 19/012,666

(22) Filed: Jan. 7, 2025

(30) Foreign Application Priority Data
Dec. 27, 2023 (CN) 202311831849.9

(51) Int. Cl. H03F 1/02; H03F 3/24

(52) U.S. Cl. CPC H03F 1/0288; H03F 3/245; H03F 2200/451

(57) ABSTRACT

A radio frequency power amplifier includes: a main amplifier, a main matching circuit, an auxiliary amplifier, an auxiliary matching circuit and an impedance conversion circuit. The main amplifier is configured to output a first amplified signal. The main matching circuit is connected between the main amplifier and the combining node and is configured to adjust a phase of the first amplified signal and raise an output impedance of the main amplifier to a first impedance. The auxiliary amplifier is configured to output a second amplified signal. The auxiliary matching circuit is connected between the auxiliary amplifier and the combining node and is configured to keep a phase of the second amplified signal and raise an output impedance of the auxiliary amplifier to a second impedance. The impedance conversion circuit is connected to the combining node and is configured to raise the impedance at the combining node to a transmission impedance.

### CROSS-REFERENCE TO RELATED APPLICATION

The present application claims priority to Chinese Patent Application No. 202311831849.9 filed on Dec. 27, 2023, the disclosure of which is hereby incorporated by reference in its entirety.

### BACKGROUND

In current mobile communication systems, such as 5th Generation Mobile Communication Technology (5G) New Radio (NR) mobile communication systems, more complex modulation schemes are adopted to improve spectrum utilization efficiency, increase data capacity and transmission rate, but their Peak to Average Power Ratio (PAPR) continues to increase, which requires a transmitting system to maintain high linearity in a large dynamic range. In order to meet linearity requirements of the system, a radio frequency Power Amplifier (PA) needs to operate in a power back-off state, but Power Added Efficiency (PAE) decreases significantly with the power back-off.

How to improve the power added efficiency of the RF power amplifier after the power back-off is an urgent problem in the field of RF power amplifiers.

### SUMMARY

In view of the above, embodiments of the present application provide a radio frequency power amplifier and an electronic device, for solving at least one technical problem existing in some implementations.

The present application relates to the field of electronic technologies, in particular to a radio frequency (RF) power amplifier and an electronic device.

According to a first aspect, an embodiment of the present application provides a radio frequency power amplifier. The radio frequency power amplifier includes a main amplifier, a main matching circuit, an auxiliary amplifier, an auxiliary matching circuit and an impedance conversion circuit. The main amplifier is configured to output a first amplified signal. The main matching circuit is connected between the main amplifier and the combining node and is configured to adjust a phase of the first amplified signal and raise an output impedance of the main amplifier to a first impedance. The auxiliary amplifier is configured to output a second amplified signal. The auxiliary matching circuit is connected between the auxiliary amplifier and the combining node and is configured to keep a phase of the second amplified signal and raise an output impedance of the auxiliary amplifier to a second impedance. An impedance at the combining node is a combined impedance of the first impedance and the second impedance, which is larger than an output impedance of the main amplifier and an output impedance of the auxiliary amplifier. The impedance conversion circuit is connected to the combining node and is configured to raise the impedance at the combining node to a transmission impedance.

In some embodiments, the first impedance is at least twice an optimal load impedance of the main amplifier and the second impedance is at least twice an optimal load impedance of the auxiliary amplifier.

In some embodiments, the impedance conversion circuit includes a balun.

In some embodiments, the main matching circuit includes a one-stage or multi-stage impedance matching circuit. Each stage impedance matching circuit includes a π-type three-element impedance matching circuit or a T-type three-element impedance matching circuit.

In some embodiments, a phase of the main matching circuit at the combining node and a phase of the auxiliary matching circuit at the combining node are the same, and the main matching circuit is configured to adjust the phase of the first amplified signal by 90 degrees.

In some embodiments, the main matching circuit includes a two-stage impedance matching circuit. The two-stage impedance matching circuit includes a first capacitor, a first inductor, a second capacitor, a second inductor, and a third capacitor. An output of the main amplifier is connected a first end of the first capacitor and a first end of the first inductor. A second end of the first inductor is connected to a first end of the second capacitor and a first end of the second inductor. Both a second end of the second inductor and a first end of the third capacitor are connected to the combining node. A second end of the first capacitor, a second end of the second capacitor and a second end of the third capacitor are all grounded.

In some embodiments, the main amplifier, the auxiliary amplifier, and the first capacitor are all integrated on a same chip, and the auxiliary matching circuit and the impedance conversion circuit, as well as the first inductor, the second capacitor, the second inductor and the third capacitor, are all arranged on a substrate coupled to the chip.

In some embodiments, the auxiliary matching circuit is configured to keep the phase of the second amplified signal constant.

In some embodiments, the auxiliary matching circuit includes a first power supply and a choke inductor. The first power supply is connected to the choke inductor and is configured to supply power to the auxiliary amplifier through the choke inductor.

In some embodiments, the auxiliary matching circuit includes an even-stage π-type impedance matching circuit. The even-stage π-type impedance matching circuit includes a first-stage π-type impedance matching circuit to a 2Nth-stage π-type impedance matching circuit in cascade, where N is a natural number.

In some embodiments, the auxiliary matching circuit further includes a fourth capacitor, a fourth inductor, a fifth inductor, a fifth capacitor, and an eighth capacitor. An output of the auxiliary amplifier is connected to a second end of the choke inductor and a first end of the fourth capacitor. A first end of the first power supply is connected to a first end of the choke inductor. A second end of the fourth capacitor is connected to a first end of the fourth inductor and a first end of the fifth inductor. A second end of the fourth inductor is connected to a first end of the eighth capacitor. Both a second end of the fifth inductor and a first end of the fifth capacitor are connected to the combining node. A second end of the first power supply, a second end of the fifth capacitor and a second end of the eighth capacitor are all grounded.

In some embodiments, each stage impedance matching circuit of the main matching circuit includes a π-type three-element impedance matching circuit. The impedance conversion circuit further includes a second power supply. The second power supply is connected to the balun and is configured to supply power to the main amplifier through the balun and the main matching circuit.

In some embodiments, the balun includes a primary coil, a secondary coil, a sixth capacitor, a seventh capacitor. Both a second end of the primary coil and a first end of the sixth capacitor are connected to the combining node. A first end of the second power supply is connected to a first end of the primary coil. The secondary coil is coupled to the primary coil. Both a first end of the secondary coil and a first end of the seventh capacitor are connected to a load. A second end of the sixth capacitor, a second end of the secondary coil and a second end of the seventh capacitor are all grounded.

In some embodiments, the output impedance of the main amplifier is less than or equal to 5 ohms and the output impedance of the auxiliary amplifier is less than or equal to 5 ohms.

According to a second aspect, an embodiment of the present application provides an electronic device including the radio frequency power amplifier of any one of the embodiments of the first aspect.

In various embodiments of the present application, the following technical effects can be achieved: 1. The power added efficiency after the deep power back-off is improved, and a larger output power is still provided after the combining node; 2. By directly adding the main matching circuit between the main amplifier and the combining node, and directly adding the auxiliary matching circuit between the auxiliary amplifier and the combining node, the output impedance of the main amplifier, the output impedance of the auxiliary amplifier and the impedance at the combining node can be improved, effectively reducing the sensitivity of low-impedance combined circuit; 3. By expanding the bandwidth of the main matching circuit and the bandwidth of the impedance conversion circuit in the output matching network respectively, the bandwidth of the RF power amplifier is effectively increased, and the risk of poor performance consistency at high, middle and low frequencies is reduced.

### BRIEF DESCRIPTION OF THE DRAWINGS

FIG. 1 is an operating schematic of a conventional Class B/Class AB power amplifier scheme.

FIG. 2 is an operating schematic of a conventional two-way Doherty power amplifier scheme.

FIG. 3A is a first operating schematic of a first radio frequency power amplifier scheme according to an embodiment of the present application.

FIG. 3B is a second operating schematic of a first radio frequency power amplifier scheme according to an embodiment of the present application.

FIG. 3C is a third operating schematic of a first radio frequency power amplifier scheme according to an embodiment of the present application.

FIG. 3D is a fourth operating schematic of a first radio frequency power amplifier scheme according to an embodiment of the present application.

FIG. 3E is a fifth operating schematic of a first radio frequency power amplifier scheme according to an embodiment of the present application.

FIG. 3F is a sixth operating schematic of a first radio frequency power amplifier scheme according to an embodiment of the present application.

FIG. 3G is a seventh operating schematic of a first radio frequency power amplifier scheme according to an embodiment of the present application.

FIG. 3H is an eighth operating schematic of the first radio frequency power amplifier scheme according to the embodiment of the present application.

FIG. 3I is a ninth operating schematic of the first radio frequency power amplifier scheme according to the embodiment of the present application.

FIG. 4 is an operating schematic of a second radio frequency power amplifier scheme according to an embodiment of the present application.

### DETAILED DESCRIPTION

Hereinafter, the present application will be described in more detail with reference to the accompanying drawings and implementations. It should be noted that following specific embodiments described in the present application are merely for illustration of the present application, and are not intended to limit the present application.

In mobile communication systems such as mobile phones, terminal products such as mobile phones mostly realize power amplification through Class B or Class AB power amplifier solutions.

Referring to FIG. 1, a radio frequency power amplifier 100 in a conventional class B/class AB power amplifier scheme includes a class B/class AB power amplifier 101, an impedance converter 102, and a load 104. The Class B/Class AB power amplifier 101 amplifies a received input signal and outputs it to the impedance converter 102. The impedance converter 102 is configured to raise an impedance of the class B/class AB power amplifier 101 to a transfer impedance of 50 ohms. An impedance of the load 104 is 50 ohms. Herein, the capacitor C1 may be used to block direct current (DC).

A power added efficiency of this kind of conventional RF power amplifier 100 is seriously reduced after high-power back-off, and a power consumption of the RF power amplifier is greatly increased, which cannot meet requirements of mobile communication systems. In addition, terminal power amplifiers such as mobile phones are manufactured by gallium arsenide (GaAs) or Silicon-On-Insulator (SOI) processes, and therefore a power supply voltage of the RF power amplifier is low, usually less than 5V. However, in the current mobile communication system, output power requirement of the conventional RF power amplifier 100 is further increased. For a high-power output realized by multi-tube parallel connection, the number of power tubes is also required to be increased, and its output impedance is also further reduced. Due to the lower output impedance, the sensitivity of the insertion loss of an output matching network to the impedance is increased, and bandwidth requirement of an impedance matching network of the RF power amplifier 100 is further improved.

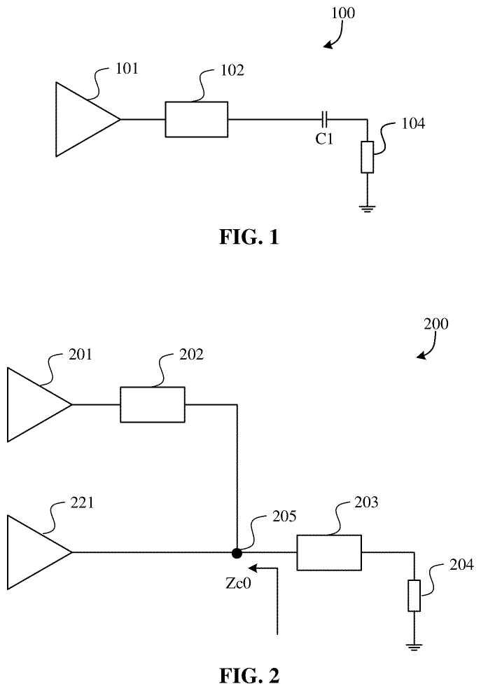

Referring to FIG. 2, a radio frequency power amplifier 200 in the conventional two-way Doherty power amplifier scheme includes a main amplifier 201, a main matching circuit 202, an auxiliary amplifier 221, an impedance conversion circuit 203, and a load 204. The main amplifier 201 is configured to output a first amplified signal. The main matching circuit 202 is connected between the main amplifier 201 and a combining node 205 and is configured to adjust a phase of the first amplified signal. The auxiliary amplifier 221 is configured to output a second amplified signal. Impedance Zc0 at the combining node 205 is a combining impedance of the main way and the auxiliary way. The impedance conversion circuit 203 is connected between the combining node 205 and a load 205 and is configured to raise the impedance at the combining node 205 to a transmission impedance. The impedance of the load 204 is 50 ohms.

In the current mobile communication system, for example, in the 3G/4G communication system, an operating bandwidth of the conventional two-way Doherty power amplifier in each frequency band is narrow. However, in the 5G New Radio (NR) mobile communication system, the operating bandwidth is relatively wide, for example, the bandwidth for N77 is 900 MHz. The conventional amplifier has a narrow bandwidth, which will lead to a large difference in amplifier performance at high, medium and low frequency, poor consistency in mass production and other issues.

In addition, in low-voltage processes such as GaAs or SOI, the impedance Zc0 at the combining node 205 in the conventional two-way Doherty power amplifier is low, which will introduce more sensitivity problems and increase the requirements of the main matching circuit 202 and the impedance conversion circuit 203 on bandwidth and insertion loss.

In view of the above, in order to solve at least one technical problem existing in some implementations, embodiments of the present application provide a radio frequency power amplifier and an electronic device, which effectively improve the power added efficiency after deep power back-off and for which the bandwidth is larger in the current mobile communication systems.

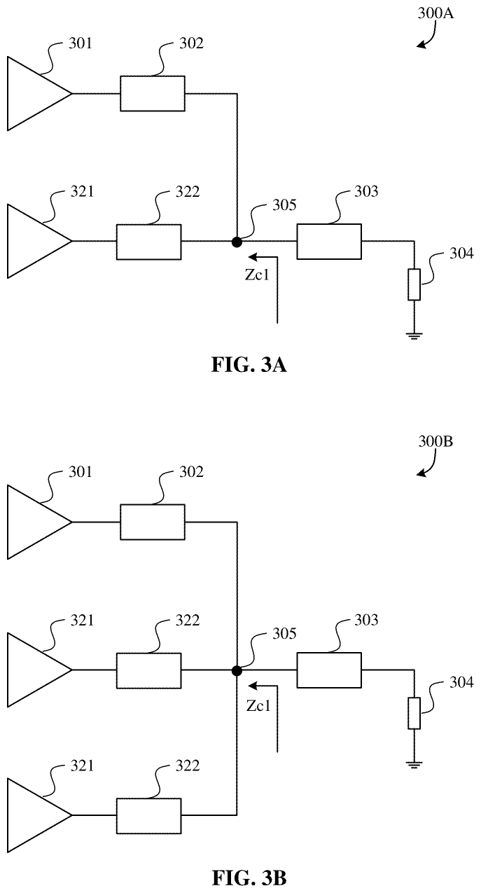

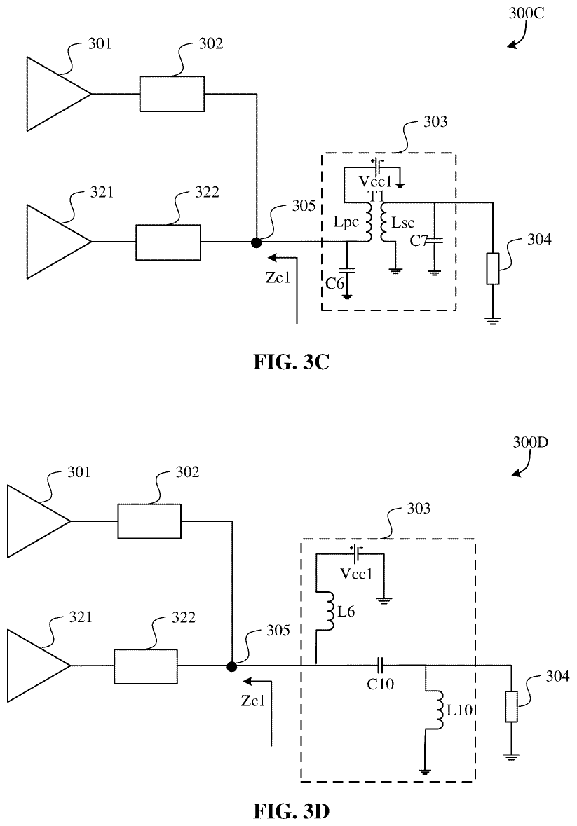

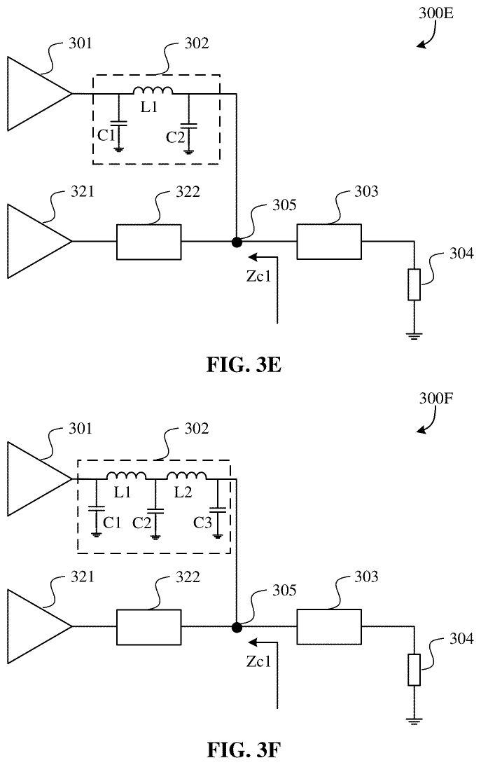

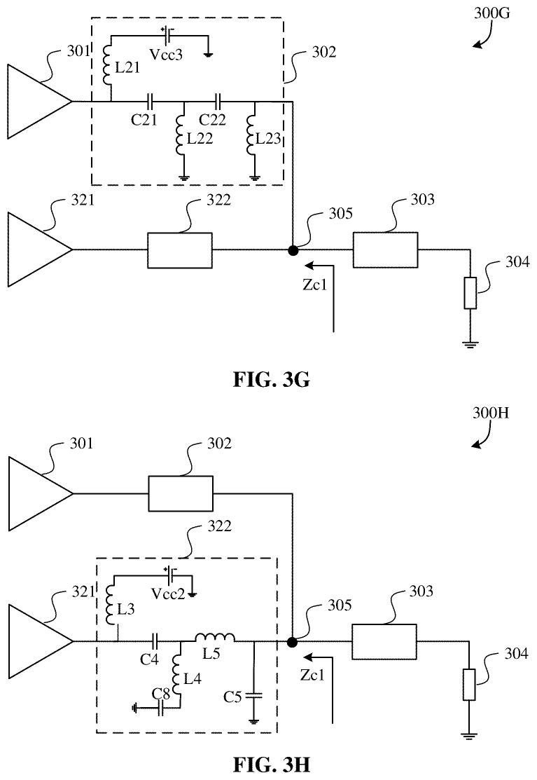

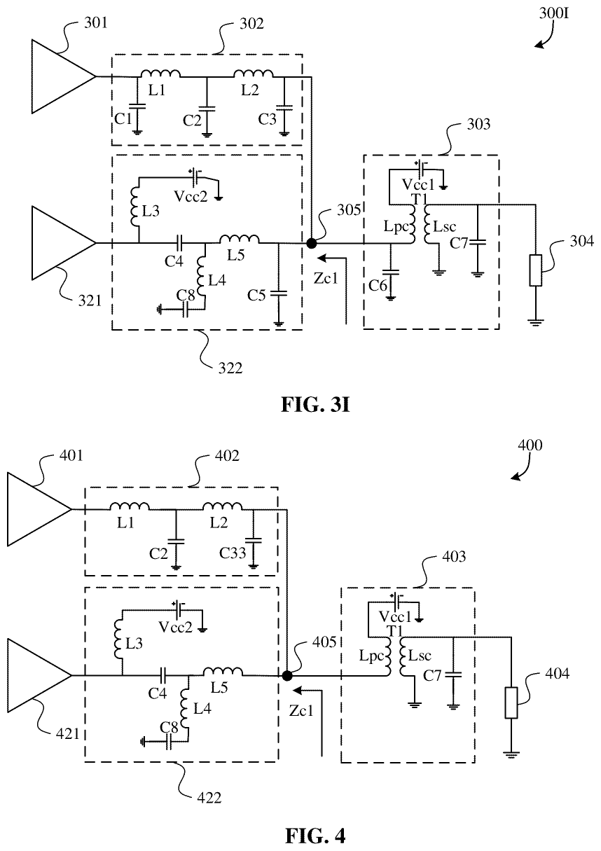

Referring to FIG. 3A, in a first aspect, an embodiment of the present application provides a radio frequency power amplifier 300A. The radio frequency power amplifier 300A includes a main amplifier 301, a main matching circuit 302, an auxiliary amplifier 321, an auxiliary matching circuit 322 and an impedance conversion circuit 303. The main amplifier 301 is configured to output a first amplified signal. The main matching circuit 302 is connected between the main amplifier 301 and a combining node 305 and is configured to adjust a phase of the first amplified signal and raise an output impedance of the main amplifier 301 to a first impedance. The auxiliary amplifier 321 is configured to output a second amplified signal. The auxiliary matching circuit 322 is connected between the auxiliary amplifier 321 and the combining node 305 and is configured to keep a phase of the second amplified signal and raise an output impedance of the auxiliary amplifier 321 to the second impedance. The impedance Zc1 at the combining node 305 is a combined impedance of the first impedance and the second impedance, which is larger than the output impedance of the main amplifier 301 and the output impedance of the auxiliary amplifier 321. The impedance conversion circuit 303 is connected to the combining node 305 and is configured to raise the impedance at the combining node 305 to the transmission impedance.

In some embodiments, a radio frequency power amplifier may be configured as a combination of 2-way, 3-way, or more-way Doherty power amplifiers. Different numbers of multi-channel Doherty power amplifiers can be optionally configured according to different circuit designs. Exemplarily, referring to FIG. 3A, the radio frequency power amplifier 300A may be configured with two ways: the first way includes a main amplifier 301 and a main matching circuit 302 which are connected to a combining node 305, and the second way includes a secondary amplifier 321 and a secondary matching circuit 322 which are connected to the combining node 305.

In other examples, a radio frequency power amplifier 300B illustrated with reference to FIG. 3B may be configured with three ways: the first way includes a main amplifier 301 and a main matching circuit 302 which are connected to a combining node 305, the second way includes an auxiliary amplifier 321 and an auxiliary matching circuit 322 which are connected to the combining node 305, and the third way includes a circuit connected to the combining node 305 and having a configuration which is the same as the configuration of the auxiliary amplifier 321 and the auxiliary matching circuit 322.

It should be noted that components/circuits/nodes/impedances and the like identified by the same reference numerals in FIGS. 3A to 3I are understood as the same or similar components/circuits/nodes/impedances. The module structures in each of FIGS. 3A to 3I may be interchangeable, and the impedance matching structure of each module may be fully or partially provided as an adjustable structure to perform switching when different frequency bands are switched.

In some embodiments, the first impedance is at least twice an optimal load impedance Ropt_m of the main amplifier 301 and the second impedance is at least twice an optimal load impedance Ropt_p of the auxiliary amplifier 321. In some specific embodiments, the first impedance is a first multiple of the optimal load impedance Ropt_m of the main amplifier 301, and the second impedance is a second multiple of the optimal load impedance Ropt_p of the auxiliary amplifier 321. The first multiple may be the same as or different from the second multiple. For example, the first impedance is 3 Ropt_m and the second impedance is 3 Ropt_p. For another example, the first impedance is 4 Ropt_m, and the second impedance is 2 Ropt_p. For another example, the first impedance is 2 Ropt_m or 5 Ropt_m, and the second impedance is 4 Ropt_p, 5 Ropt_p, or the like. It should be noted that the first multiple and the second multiple may be non-integers, for example, 2.5, 3.2, 4.8, or the like.

Here and below, a two-way Doherty power amplifier scheme will be described as an example, and the two-way Doherty power amplifier scheme is not used to limit the embodiments of the present application.

Referring to FIG. 3A, an operation principle of the radio frequency power amplifier 300A is as follows. When the power is low, the main amplifier 301 is turned on and the auxiliary amplifier 321 is turned off. The auxiliary amplifier 321 realizes the open circuit characteristic since it operates in Class C and is not turned on. The auxiliary matching circuit 322 maintains the Class C open circuit characteristic of the auxiliary amplifier 321, and therefore the output impedance of the auxiliary amplifier 321 is infinite. The main amplifier 301 operates in Class AB, and the main matching circuit 302 adjusts the phase of the main amplifier 301 and raises the output impedance of the main amplifier 301, so that the output impedance under high impedance is Rmod (the load modulation impedance Rmod is high impedance at low power). At this time, the main matching circuit 302 has high efficiency and good linearity. At high power, the auxiliary amplifier 321 is turned on, and the output impedance of the main amplifier 301 is converted from Rmod to 4Ropt_m (Ropt_m is the optimal load impedance of the main amplifier 301) due to the pull of the active load of the auxiliary amplifier 321. The output impedance of the auxiliary amplifier 321 after the auxiliary matching circuit 321 becomes 4Ropt_p (Ropt_p is the optimal load impedance of the auxiliary amplifier 321). At this time, the main amplifier 301 and the auxiliary amplifier 321 output at high power together, and the impedance Zc1 at the combining node 305 is converted from the conventional Ropt/2 (Ropt is the optimal load impedance of the main amplifier 301 and the auxiliary amplifier 321) to 2 Ropt. The impedance conversion circuit 303 is configured to raise the impedance Zc1 at the combining node 305 to the transmission impedance, that is, to convert it into a 50 ohm output load. In this way, the RF power amplifier using Doherty technology effectively realizes the improvement of power added efficiency after deep power back-off, and has a larger bandwidth.

Referring to a radio frequency power amplifier 300C shown in FIG. 3C, in some embodiments, the impedance conversion circuit 303 includes a balun. In some specific embodiments, the balun includes a transformer T1, a sixth capacitor C6 and a seventh capacitor C7. The transformer T1 has an impedance conversion ratio of TF for wide bandwidth impedance conversion. The sixth capacitor C6 and the seventh capacitor C7 are configured for impedance tuning.

In some embodiments, the sixth capacitor C6 and/or the seventh capacitor C7 may be configured as a variable capacitor so that the impedance transformation can be adjusted according to different radio frequency signals. For example, the sixth capacitor C6 and/or the seventh capacitor C7 are provided as variable capacitors, which may perform impedance conversion adjustment on signals of different frequency bands.

In the embodiments of the present application, the impedance conversion is realized by the balun, and therefore the bandwidth of the radio frequency power amplifier can be further improved.

In some specific embodiments, the impedance conversion circuit further includes a second power supply Vcc1. The second power supply Vcc1 is connected to the balun and supplies power to the main amplifier and/or the auxiliary amplifier through the balun. Herein, the second power supply multiplexes the inductor in the balun (refer to the primary coil Lpc of the balun in FIG. 3C). That is, the second power supply uses the inductor of the balun as an inductor to avoid the interference of the radio frequency signal on the second power supply.

Referring to a radio frequency power amplifier 300D shown in FIG. 3D, in some embodiments, an impedance conversion circuit 303 of the radio frequency power amplifier 300D includes a second power supply Vcc1 and a choke inductor L6. The choke inductor L6 is located between the second power supply Vcc1 and the combining node 305. A one-stage π-type impedance matching circuit formed by the choke inductor L6, a tenth inductor L10, and a tenth capacitor C10 is located between the combining node 305 and the load 304. The second power supply Vcc1 may supply power to the main amplifier 301 and/or the auxiliary amplifier 321 via the choke inductor L6.

Referring to FIGS. 3E, 3F, and 3G, in some embodiments, the main matching circuit 302 includes a one-stage or multi-stage impedance matching circuit. Each stage impedance matching circuit includes a π-type three-element impedance matching circuit, a T-type three-element impedance matching circuit, or an L-type two-element impedance matching circuit.

The one-stage π-type three-element impedance matching circuit may be formed by one inductor and two capacitors. For example, referring to a radio frequency power amplifier 300E shown in FIG. 3E, the π-type three-element impedance matching circuit may be formed by a first capacitor C1, a first inductor L1, and a second capacitor C2. A first end of the first capacitor C1 and a first end of the first inductor L1 are connected and serve as an input of the π-type three-element impedance matching circuit. A first end of the second capacitor C2 and a second end of the first inductor L1 are connected and serve as an output of the π-type three-element impedance matching circuit. Both a second end of the first capacitor C1 and a second end of the second capacitor C2 are grounded.

In some embodiments, the main matching circuit 302 includes a two-stage impedance matching circuit. Each stage impedance matching circuit includes a π-type three-element impedance matching circuit. The two-stage π-type three-element impedance matching circuit includes a first-stage π-type three-element impedance matching circuit and a second-stage π-type three-element impedance matching circuit in cascade, and may be formed by two inductors and three capacitors. Exemplarily, referring to a radio frequency power amplifier 300F shown in FIG. 3F, the first-stage π-type three-element impedance matching circuit includes a first capacitor C1, a first inductor L1, and a second capacitor C2. A first end of the first capacitor C1 is connected to a first end of the first inductor L1. A first end of the second capacitor C2 is connected to a second end of the first inductor L1. A second end of the first capacitor C1 and a second end of the second capacitor C2 are grounded. The second-stage π-type three-element impedance matching circuit includes the second capacitor C2, a second inductor L2 and a third capacitor C3. A first end of the second capacitor C2 is connected to a first end of the second inductor L2. A first end of the third capacitor C3 is connected to a second end of the second inductor L2. A second end of the second capacitor C2 and a second end of the third capacitor C3 are grounded.

The one-stage π-type three-element impedance matching circuit may be formed by one capacitor and two inductors, and can be understood by replacing the capacitor with an inductor and replacing the inductor with a capacitor in the π-type three-element impedance matching circuit in the above embodiment, and will not be repeated here.

In some specific embodiments, the main matching circuit 302 includes a two-stage impedance matching circuit. Each stage impedance matching circuit includes a π-type three-element impedance matching circuit. Exemplarily, referring to a radio frequency power amplifier 300G shown in FIG. 3G, the first-stage π-type three-element impedance matching circuit includes a twenty-first inductor L21, a twenty-first capacitor C21, and a twenty-second inductor L22. A second end of the twenty-first inductor L21 is connected to a first end of the twenty-first capacitor C21. A second end of the twenty-first capacitor C21 is connected to a first end of the twenty-second inductor L22. The second-stage π-type three-element impedance matching circuit includes the twenty-second inductor L22, a twenty-second capacitor C22 and a twenty-third inductor L23. A second end of the twenty-second inductor L22 is connected to a first end of the twenty-second capacitor C22. A second end of the twenty-second capacitor C22 is connected to a first end of the twenty-third inductor L23. A second end of the twenty-second inductor L22 and a second end of the twenty-third inductor L23 are grounded. A first end of the twenty-first inductor L21 is grounded via a third power supply Vcc3. The third power supply Vcc3 supplies power to the main amplifier 301 via the twenty-first inductor L21. In this embodiment, the impedance matching circuit multiplexes the inductor (i.e. the twenty-first inductor L21) of the amplifier, thereby reducing the overall area.

In some embodiments, each stage impedance matching circuit includes a T-type three-element impedance matching circuit, a one-stage T-type three-element impedance matching circuit may be a “T” shaped circuit formed by one capacitor and two inductors, or a “T” shaped circuit formed by one inductor and two capacitors. In some specific embodiments, the arrangement of capacitors and inductors in the one-stage T-type three-element impedance matching circuit may depend on placement position of a phase shifter at a back end of a power divider.

When the main matching circuit includes a multi-stage impedance matching circuit, the bandwidth can be improved, and the impedance can be improved while adjusting the phase.

Referring to FIGS. 3E, 3F, and 3G, in some embodiments, the phase of the main matching circuit 302 at the combining node 305 and the phase of the secondary matching circuit 322 at the combining node 305 are the same, and the main matching circuit 302 adjusts the phase of the first amplified signal by 90 degrees.

In the embodiments of the present application, the main matching circuit 302 raises the output impedance of the main amplifier 301 to the first impedance while adjusting the phase of the first amplified signal The output phase angle of the main circuit is 90 degrees. The main matching circuit 302 can improve the impedance at the combining point without affecting the performance of the amplifier, thereby effectively reducing the sensitivity of the combined circuit as compared with some implementations.

Referring to a radio frequency power amplifier 300F shown in FIG. 3F, in some embodiments, the main matching circuit 302 includes a two-stage impedance matching circuit. The two-stage impedance matching circuit includes a first capacitor C1, a first inductor L1, a second capacitor C2, a second inductor L2, and a third capacitor C3. An output of the main amplifier 301 is connected to a first end of the first capacitor C1 and a first end of the first inductor L1. A second end of the first inductor L1 is connected to a first end of the second capacitor C2 and a first end of the second inductor L2. Both a second end of the second inductor L2 and a first end of the third capacitor C3 are connected to the combining node 305. A second end of the first capacitor C1, a second end of the second capacitor C2 and a second end of the third capacitor C3 are all grounded.

Thus, the two-stage impedance matching circuit includes a first stage π-type impedance matching circuit and a second stage π-type impedance matching circuit in cascade. The first stage π-type impedance matching circuit includes the first capacitor C1, the first inductor L1 and the second capacitor C2. The second stage π-type impedance matching circuit includes the second capacitor C2, the second inductor L2 and the third capacitor C3. Here, the second capacitor C2 may serve as a common capacitor of the first stage π-type impedance matching circuit and the second stage π-type impedance matching circuit.

The auxiliary matching circuit raises the output impedance of the auxiliary amplifier to the second impedance and keeps the phase of the second amplified signal constant.

Referring to a radio frequency power amplifier 300H shown in FIG. 3H, in some embodiments, the auxiliary matching circuit 322 includes a first power supply Vcc2 and a choke inductor L3. The first power supply Vcc2 is connected to the choke inductor L3, and supplies power to the auxiliary amplifier 321 through the choke inductor L3.

In this way, the choke inductor L3 not only participates in the matching of the auxiliary amplifier 321, but also isolates the radio frequency signal from the first power supply Vcc2, so that the radio frequency signal does not affect the power supply.

Referring to the radio frequency power amplifier 300H shown in FIG. 3H, in some embodiments, the auxiliary matching circuit 322 includes an even-stage π-type impedance matching circuit, and the even-stage π-type impedance matching circuit includes a first-stage π-type impedance matching circuit to a 2Nth-stage π-type impedance matching circuit in cascade, where N is a natural number.

Referring to the radio frequency power amplifier 300H shown in FIG. 3H, in some embodiments, the auxiliary matching circuit 322 further includes a fourth capacitor C4, a fourth inductor L4, a fifth inductor L5, a fifth capacitor C5, and an eighth capacitor C8. An output of the auxiliary amplifier 321 is connected to a second end of the choke inductor L3 and a first end of the fourth capacitor C4. A first end of the first power supply Vcc2 is connected to a first end of the choke inductor L3. A second end of the fourth capacitor C4 is connected to both a first end of the fourth inductor L4 and a first end of the fifth inductor L5. A second end of the fourth inductor L4 is connected to a first end of the eighth capacitor C8. Both a second end of the fifth inductor L5 and a first end of the fifth capacitor C5 are connected to the combining node 305. A second end of the first power supply Vcc2, a second end of the fifth capacitor C5 and a second end of the eighth capacitor C8 are all grounded.

As such, the auxiliary matching circuit 322 includes a two-stage π-type impedance matching circuit in cascade and an eighth capacitor C8. The two-stage π-type impedance matching circuit includes a first-stage π-type impedance matching circuit formed by a third inductor L3, a fourth capacitor C4 and a fourth inductor L4, and a second-stage π-type impedance matching circuit formed by the fourth inductor L4, a fifth inductor L5 and a fifth capacitor C5. The eighth capacitor C8 blocks a direct current (DC) and does not participate in the matching of the auxiliary matching circuit 322, avoiding direct grounding of the DC power supply, such as the second power supply Vcc1.

In some embodiments, inductors in the auxiliary matching circuit 322 may be provided as adjustable inductors, or capacitors in the auxiliary matching circuit 322 may be provided as adjustable capacitors, so that the impedance conversion can be adjusted according to different radio frequency signals. For example, impedance conversion adjustment is performed on signals of different frequency bands. Exemplarily, each of the third inductor L3, the fourth inductor L4, and the fifth inductor L5 is provided as an adjustable capacitor or each of the fourth capacitor C4 and the fifth capacitor C5 are provided as an adjustable capacitor, which can be used to perform impedance conversion adjustment on signals of different frequency bands.

In some embodiments, the auxiliary matching circuit 322 includes a four-stage π-type impedance matching circuits which include a first-stage π-type impedance matching circuit to a fourth-stage π-type impedance matching circuit in cascade. The four-stage π-type impedance matching circuits can be understood as being obtained by coupling two above mentioned two-stage π-type impedance matching circuits in series. The specific details of the four-stage π-type impedance matching circuit will not be repeated here.

In the current mobile communication system, due to the high frequency, capacitance values and inductor values of lumped devices change greatly with the frequency. In the embodiment of the present application, the capacitance is reduced by using the multi-stage π-type impedance matching circuit, which reduces the drastic change of the capacitance value with the frequency in a wide bandwidth. The auxiliary matching circuit of the radio frequency power amplifier is a multi-stage π-type impedance matching circuit, which can raise the output impedance of the auxiliary amplifier to the second impedance while keeping the phase of the second amplified signal constant.

Referring to a radio frequency power amplifier 300I shown in FIG. 3I, in some embodiments, each stage impedance matching circuit of the main matching circuit 302 includes a π-type three-element impedance matching circuit. The impedance conversion circuit 303 further includes a second power supply Vcc1. The second power supply Vcc1 is connected to a balun, and supplies power to the main amplifier 301 through the balun and the main matching circuit 302.

In some specific embodiments, the balun includes a primary coil Lpc located between the second power supply Vcc1 and the combining node and the second power supply Vcc1 supplies power to the main amplifier 301 through the primary coil Lpc of the balun and the main matching circuit 302. In some specific embodiments, the eighth capacitor C8 blocks direct current, to avoid direct grounding of the second power supply Vcc1.

In the embodiments of the present application, the second power supply of the radio frequency power amplifier and the balun constitute a multiplexing structure, and the power can be supplied to the main amplifier through the balun and the main matching circuit. When the main amplifier operates normally, the second power supply is required to supply power and a choke inductor (refer to the primary coil Lpc of the balun in FIG. 3I) is required to isolate the radio frequency signal from the DC signal to ensure the stability of the second power supply.

FIG. 4 is an operating schematic of a second radio frequency power amplifier scheme according to an embodiment of the present application. Referring to a radio frequency power amplifier 400 shown in FIG. 4, in some embodiments, a main amplifier 401, an auxiliary amplifier 421, and a first capacitor C1 (refer to FIG. 3I) are all integrated on a same chip, and an auxiliary matching circuit 422 and an impedance conversion circuit 403, as well as a first inductor L1, a second capacitor C2, a second inductor L2, and a third capacitor C3, are all arranged on a substrate coupled to the chip.

The radio frequency power amplifier 400 in FIG. 4 can be understood with reference to the radio frequency power amplifier 400 in FIG. 3I. That is, the main amplifier 401, a main matching circuit 402, the auxiliary amplifier 421, the auxiliary matching circuit 422, the impedance conversion circuit 403, and a impedance node 405 in FIG. 4 can be understood with reference to the main amplifier 301, the main matching circuit 302, the auxiliary amplifier 321, the auxiliary matching circuit 322, the impedance conversion circuit 303, and the impedance node 305 in FIG. 3I, respectively.

It should be noted that the first capacitor C1 (refer to FIG. 3I) absent from the main matching circuit 402 in FIG. 4 is not used to illustrate that the first capacitor C1 is absent from the actual main matching circuit 402, but is used to illustrate that the integration manner for the first capacitor C1 of the main matching circuit 402 in FIG. 4 is different from the integration manner for the first inductor L1, the second capacitor C2, the second inductor L2, and the third capacitor C3 of the main matching circuit 402 in FIG. 4. That is, the first capacitor C1 of the main matching circuit 402 which is not shown in FIG. 4, the main amplifier 401 and the auxiliary amplifier 421 are integrated on a same chip, and the first inductor L1, the second capacitor C2, the second inductor L2, and the third capacitor C3 of the main matching circuit 402 which is shown in FIG. 4 are arranged in a substrate coupled to the chip as a discrete device.

Thus, the main amplifier 401, the auxiliary amplifier 421, and the first capacitor C1 (not shown in FIG. 4) of the radio frequency power amplifier 400 are presented in the form of an integrated circuit and are all integrated on the same chip, and the auxiliary matching circuit 422 and the impedance conversion circuit 403 of the radio frequency power amplifier 400, as well as the first inductor L1, the second capacitor C2, the second inductor L2, and the third capacitor C3 are arranged on the substrate coupled to the chip as a discrete device.

In some specific embodiments, the third capacitor C3, the fifth capacitor C5, and the sixth capacitor C6 (refer to FIG. 3I) are equivalently combined into one capacitor (refer to a ninth capacitor C33 in FIG. 4).

In some specific embodiments, the first inductor L1, the second inductor L2, the third inductor L3, and the transformer T1 of the impedance conversion circuit 303 may be formed by winding wires on a substrate.

In the current mobile communication system, due to the high frequency, the capacitance and inductance values of lumped devices change greatly with the frequency. The first inductor, the second inductor, the third inductor and the transformer are realized through on-chip winding, which effectively reduces the risk of the large difference in performance at high, medium and low frequencies and production fluctuation.

The radio frequency power amplifiers provided by the embodiments of the present application can meet the requirements of important indicators such as low cost and miniaturization of the radio frequency power amplifiers.

Referring to the radio frequency power amplifier 300I shown in FIG. 3I, in some embodiments, the balun includes a primary coil Lpc, a secondary coil Lsc, a sixth capacitor C6, a seventh capacitor C7. A second end of the primary coil Lpc and a first end of the sixth capacitor C6 are both connected to the combining node. A first end of the second power supply Vcc1 is connected to a first end of the primary coil Lpc. The secondary coil Lsc is coupled to the primary coil Lpc. A first end of the secondary coil Lsc and a first end of the seventh capacitor C7 are both connected to a load 304. A second end of the sixth capacitor C6, a second end of the secondary coil Lsc and a second end of the seventh capacitor C7 are all grounded.

Here, the transformer T1 of the balun includes a coupled primary coil Lpc and secondary coil Lsc, and an impedance conversion ratio obtained by the coupled primary coil Lpc and secondary coil Lsc may be TF, to realize wide bandwidth impedance conversion. The sixth capacitor C6 and the seventh capacitor C7 are used for impedance tuning at the combining node 305.

In the embodiments of the present application, the impedance conversion is realized by the balun, which further improves the bandwidth of the radio frequency power.

Referring to the radio frequency power amplifier 300I shown in FIG. 3I, in some embodiments, both an output impedance of the main amplifier 301 and an output impedance of the auxiliary amplifier 321 are less than or equal to 5 ohms, for example, 3 ohms, 4 ohms, etc.

In some embodiments, the output impedance of the main amplifier 301 and the output impedance of the auxiliary amplifier 321 are less than 3 ohms. The radio frequency power amplifier 300I provided by the embodiment of the present application is applicable to a radio frequency power amplifier 300I manufactured by a low-voltage process such as GaAs or SOI. The output impedance of the main amplifier 301 and the output impedance of the auxiliary amplifier 321 in the radio frequency power amplifier 300I manufactured by the low-voltage process is less than or equal to 5 ohms.

In some embodiments, the radio frequency power amplifier 300I further includes an input of the radio frequency power amplifier 300I (not shown in FIG. 3I), a drive amplifier (not shown in FIG. 3I), a power divider (not shown in FIG. 3I). Herein, the input of the radio frequency power amplifier 300I transmits an input signal to the driving amplifier, the driving amplifier distributes the driven output signal into two independent ways through the power divider (not shown in FIG. 3I), and the two ways of independent signals respectively pass through two amplifiers. One of the two amplifiers is the main amplifier 301 and the other is the auxiliary amplifier 321.

In some embodiments, the radio frequency power amplifier 300I further includes an output of the radio frequency power amplifier 300I (not shown in FIG. 3I). The load 305 is located between the output of the radio frequency power amplifier 300I and the ground, and the impedance of the load 305 is 50 ohms.

In various embodiments of the present application, the following technical effects can be achieved: 1. The power added efficiency after the deep power back-off is improved, and a larger output power is still provided after the combining node; 2. By directly adding the main matching circuit between the main amplifier and the combining node, and directly adding the auxiliary matching circuit between the auxiliary amplifier and the combining node, the output impedance of the main amplifier, the output impedance of the auxiliary amplifier and the impedance at the combining node can be improved, effectively reducing the sensitivity of low-impedance combined circuit; 3. By expanding the bandwidth of the main matching circuit and the bandwidth of the impedance conversion circuit in the output matching network respectively, the bandwidth of the RF power amplifier is effectively increased, and the risk of poor performance consistency at high, middle and low frequencies is reduced.

According to a second aspect, an embodiment of the present application provides an electronic device including the radio frequency power amplifier in any one of the embodiments of the first aspect.

Exemplarily, the radio frequency power amplifier includes a main amplifier, a main matching circuit, an auxiliary amplifier, an auxiliary matching circuit and an impedance conversion circuit. The main amplifier is configured to output a first amplified signal. The main matching circuit is connected between the main amplifier and a combining node and is configured to adjust a phase of the first amplified signal and raise an output impedance of the main amplifier to a first impedance. The auxiliary amplifier is configured to output a second amplified signal. The auxiliary matching circuit is connected between the auxiliary amplifier and the combining node and is configured to keep a phase of the second amplified signal and raise an output impedance of the auxiliary amplifier to a second impedance. The impedance at the combining node is a combined impedance of the first impedance and the second impedance and is larger than an output impedance of the main amplifier and an output impedance of the auxiliary amplifier. The impedance conversion circuit is connected to the combining node and is configured to raise the impedance at the combining node to a transmission impedance.

In several embodiments provided in the present application, it should be understood that the disclosed devices and methods may be implemented in other ways. The device embodiments described above are merely schematic. For example, the division of units is only a logical function division. In actual implementation, there may be other division methods, for example, multiple units or components may be combined, or may be integrated into another system, or some features may be ignored, or may not be implemented. Additionally, the coupling, or direct coupling, or communication connection between the components shown or discussed may be indirect coupling or communication connection through some interface, devices or units, and may be coupled electrically, mechanically, or otherwise.

The units described above as separate components may or may not be physically separated, and the components displayed as units may or may not be physical units. They can be located in one place or distributed among multiple network elements. Some or all of the units may be selected according to actual needs to achieve the purpose of the solution of the present embodiments.

In addition, in various embodiments of the present application, all functional units may be integrated into one processing unit, each unit may be separately used as one unit, or two or more units may be integrated into one unit. The above integrated unit may be implemented in the form of hardware or in the form of hardware plus software functional units.

It is to be appreciated that references throughout the specification to “one embodiment” or “an embodiment” mean that a particular feature, structure, or characteristic related to the embodiment is included in at least one embodiment of the present application. Thus, appearances of “in one embodiment” or “in an embodiment” throughout the specification do not necessarily refer to the same embodiment. Furthermore, these particular features, structures, or characteristics may be incorporated in any suitable manner in one or more embodiments. It should be appreciated that in various embodiments of the present application, the sequence numbers of the above-described processes do not mean the sequence of execution, and the sequence of execution of various processes should be determined by its function and internal logic, and should not constitute any limitation on the implementation order of the embodiments of the present application. The above-described serial numbers of the embodiments of the present application are for the purpose of description only, and do not represent the advantages and disadvantages of the embodiments.

It should be noted that, herein, the terms “comprising,” “including,” or any other variation thereof are intended to encompass a non-exclusive inclusion such that a process, method, article, or apparatus that includes a series of elements includes not only those elements, but also other elements that are not explicitly listed, or elements inherent to such a process, method, article, or apparatus. Without further limitation, an element defined by the statement “including a” does not preclude the presence of additional identical elements in a process, method, article, or apparatus that includes the element.

The foregoing includes only embodiments of the present application, but the scope of protection of the present application is not limited thereto, and any person skilled in the art can easily conceive of changes or substitutions within the technical scope disclosed in the present application, and should be covered within the scope of protection of the present application.

We claim:

1. A radio frequency power amplifier, comprising:
a main amplifier configured to output a first amplified signal;
a main matching circuit connected between the main amplifier and a combining node and configured to adjust a phase of the first amplified signal and raise an output impedance of the main amplifier to a first impedance;
an auxiliary amplifier configured to output a second amplified signal;
an auxiliary matching circuit connected between the auxiliary amplifier and the combining node and configured to keep a phase of the second amplified signal and raise an output impedance of the auxiliary amplifier to a second impedance, wherein an impedance at the combining node is a combined impedance of the first impedance and the second impedance, which is larger than an output impedance of the main amplifier and an output impedance of the auxiliary amplifier; and
an impedance conversion circuit connected to the combining node and configured to raise the impedance at the combining node to a transmission impedance.

2. The radio frequency power amplifier of claim 1, wherein the first impedance is at least twice an optimum load impedance of the main amplifier and the second impedance is at least twice an optimum load impedance of the auxiliary amplifier.

3. The radio frequency power amplifier of claim 1, wherein the impedance conversion circuit comprises a balun.

4. The radio frequency power amplifier of claim 3, wherein the main matching circuit comprises a one-stage or multi-stage impedance matching circuit, each stage impedance matching circuit comprises a π-type three-element impedance matching circuit or a T-type three-element impedance matching circuit.

5. The radio frequency power amplifier according to claim 4, wherein a phase of the main matching circuit at the combining node and a phase of the auxiliary matching circuit at the combining node are the same, and the main matching circuit is configured to adjust the phase of the first amplified signal by 90 degrees.

6. The radio frequency power amplifier of claim 5, wherein the main matching circuit comprises a two-stage impedance matching circuit, the two-stage impedance matching circuit comprises a first capacitor, a first inductor, a second capacitor, a second inductor, and a third capacitor, wherein
an output of the main amplifier is connected to a first end of the first capacitor and a first end of the first inductor, a second end of the first inductor is connected to a first end of the second capacitor and a first end of the second inductor, both a second end of the second inductor and a first end of the third capacitor are connected to the combining node, and a second end of the first capacitor, a second end of the second capacitor and a second end of the third capacitor are all grounded.

7. The radio frequency power amplifier of claim 6, wherein the main amplifier, the auxiliary amplifier and the first capacitor are all integrated on a same chip, the auxiliary matching circuit and the impedance conversion circuit, as well as the first inductor, the second capacitor, the second inductor, and the third capacitor, are all arranged on a substrate coupled to the chip.

8. The radio frequency power amplifier of claim 1, wherein the auxiliary matching circuit is configured to keep the phase of the second amplified signal constant.

9. The radio frequency power amplifier of claim 8, wherein the auxiliary matching circuit comprises a first power supply and a choke inductor, the first power supply is connected to the choke inductor and is configured to supply power to the auxiliary amplifier through the choke inductor.

10. The radio frequency power amplifier of claim 9, wherein the auxiliary matching circuit comprises an even-stage π-type impedance matching circuit and the even-stage π-type impedance matching circuit comprises a first-stage π-type impedance matching circuit to a 2Nth-stage π-type impedance matching circuit in cascade, where N is a natural number.

11. The radio frequency power amplifier of claim 10, wherein the auxiliary matching circuit further comprises a fourth capacitor, a fourth inductor, a fifth inductor, a fifth capacitor, and an eighth capacitor, wherein
an output of the auxiliary amplifier is connected to a second end of the choke inductor and a first end of the fourth capacitor, a first end of the first power supply is connected to a first end of the choke inductor, a second end of the fourth capacitor is connected to both a first end of the fourth inductor and a first end of the fifth inductor, a second end of the fourth inductor is connected to the first end of the eighth capacitor, both a second end of the fifth inductor and a first end of the fifth capacitor are connected to the combining node, and a second end of the first power supply, a second end of the fifth capacitor and a second end of the eighth capacitor are all grounded.

12. The radio frequency power amplifier of claim 4, wherein each stage impedance matching circuit of the main matching circuit comprises the π-type three-element impedance matching circuit and the impedance conversion circuit further comprises a second power supply, and wherein the second power supply is connected with the balun and is configured to supply power to the main amplifier through the balun and the main matching circuit.

13. The radio frequency power amplifier of claim 12, wherein the balun comprises a primary coil, a secondary coil, a sixth capacitor, a seventh capacitor, wherein
both a second end of the primary coil and a first end of the sixth capacitor are connected to the combining node, a first end of the second power supply is connected to a first end of the primary coil, the secondary coil is coupled to the primary coil, both a first end of the secondary coil and a first end of the seventh capacitor are connected to a load, and a second end of the sixth capacitor, a second end of the secondary coil and a second end of the seventh capacitor are all grounded.

14. The radio frequency power amplifier of claim 1, wherein the output impedance of the main amplifier is less than or equal to 5 ohms and the output impedance of the auxiliary amplifier is less than or equal to 5 ohms.

15. An electronic device comprising the radio frequency power amplifier of claim 1.
